(19) United States
(12) Patent Application Publication
(10) Pub. No.: US 2023/0352468 A1
(43) Pub. Date: Nov. 2, 2023

(54) PACKAGING STRUCTURE AND PACKAGING METHOD

(71) Applicants: Semiconductor Manufacturing International (Shanghai) Corporation, Shanghai (CN); Semiconductor Manufacturing International (Beijing) Corporation, Beijing (CN)

(72) Inventor: Jisong Jin, Shanghai (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 18/096,091

(22) Filed: Jan. 12, 2023

(30) Foreign Application Priority Data
Apr. 29, 2022 (CN) 202210465441.3

(51) Int. Cl. H01L 25/18; H01L 23/538; H01L 23/48; H01L 23/00; H01L 23/31; H01L 23/42; H01L 23/053; H01L 25/00

(52) U.S. Cl. CPC H01L 25/18; H01L 23/5386; H01L 23/481; H01L 24/16; H01L 24/32; H01L 24/73; H01L 23/3185; H01L 23/42; H01L 23/053; H01L 25/50; H01L 24/81; H01L 24/83; H01L 24/92; H01L 2224/16225; H01L 2224/16146; H01L 2224/32225; H01L 2224/73204; H01L 2224/81; H01L 2224/83; H01L 2224/92125

(57) ABSTRACT

This disclosure relates to packaging method and a packaging structure. The packaging structure includes: a substrate, including a bonding surface, a chipset, bonded to the bonding surface and including a plurality of first chips stacked along a longitudinal direction, where the first chip adjacent to the substrate is used as a bottom chip, each of the rest of the first chips is used as a top chip; and a second chip, bonded to the bottom chip exposed from the top chip and to the bonding surface on a side of the chipset, where the second chip, the bottom chip, the top chip, and the substrate are electrically connected, and a projection of the second chip and a projection of the bottom chip on a projection plane parallel to the bonding surface partially overlap. The present disclosure helps improve a speed of communication between chips.

### CROSS REFERENCE TO RELATED APPLICATIONS

This application is based on and claims priority to Chinese patent Application No. 202210465441.3, filed Apr. 29, 2022, the entire content of which is incorporated herein by reference.

### TECHNICAL FIELD

The present disclosure relates to the field of semiconductor manufacturing, and in particular, to a packaging structure and a packaging method.

### BACKGROUND

A conventional chip manufacturing technology is being pushed to a limit in terms of a size of a single chip. However, applications are eager for a latest technology to realize a large-scale integrated circuit, and it is a challenge to achieve high-speed and small-volume interconnection between chips.

A current solution is a relatively small integrated circuit with a silicon bridge (Si bridge) chip being embedded in a silicon substrate. The Si bridge is used to realize interconnection between chips, thereby providing heterogeneous chip packaging.

However, current packaging structures are relatively complex, and a speed of communication between chips is to be improved.

### SUMMARY

The forms of the present disclosure provide a packaging structure and a packaging method, to simplify a packaging structure and improve a speed of communication between chips.

In an aspect of the present disclosure, a packaging structure is provided. The packaging structure may include: a substrate, including a bonding surface, a chipset, bonded to the bonding surface and including a plurality of first chips stacked along a longitudinal direction, where the first chip adjacent to the substrate is used as a bottom chip, each of the rest of the first chips is used as a top chip, the bottom chip is electrically connected to the substrate and the adjacent first chip, and a portion of the bottom chip is exposed from the top chip; and a second chip, bonded to the bottom chip exposed from the top chip and to the bonding surface on a side of the chipset, where the second chip, the bottom chip, the top chip, and the substrate are electrically connected, and a projection of the second chip and a projection of the bottom chip on a projection plane parallel to the bonding surface partially overlap.

In another aspect of the present disclosure, a packaging method is provided. The packaging method may include: providing a substrate including a bond surface; providing a chipset, where the chipset includes a plurality of first chips stacked along a longitudinal direction, the first chip at a bottom of the chipset is used as a bottom chip, each of the rest of the first chips is used as a top chip, adjacent first chips along the longitudinal direction are electrically connected, and a portion of the bottom chip is exposed from the top chip; bonding the chipset to the bond surface, where in the chipset, the bottom chip is adjacent to the bond surface, and the bottom chip is electrically connected to the substrate; providing a second chip; and bonding the second chip to the bottom chip exposed from the top chip and to the bonding surface on a side of the chipset, where the second chip, the bottom chip, the top chip, and the substrate are electrically connected, and a projection of the second chip and a projection of the bottom chip on the bonding surface partially overlap.

Compared with the prior art, the forms of the present disclosure have the following advantages.

According to the packaging structure provided in the forms of the present disclosure, in the chipset, a portion of the bottom chip is exposed from the top chip, and the second chip is bonded to the bottom chip exposed from the top chip and the bonding surface on the side of the chipset. In the forms of the present disclosure, since a portion of the bottom chip is exposed from the top chip, a space can be provided for bonding the second chip to the bottom chip, so that a portion of the second chip can be bonded to the bottom chip exposed from the top chip, thereby electrically connecting each first chip in the chipset to the second chip. In this way, the electrical connection between the first chip and the second chip can be realized merely by using the bottom chip in the chipset without using a bridge, which helps simplify a structure and shorten a transmission path between the first chip and the second chip, thereby improving a speed of communication between the first chip and the second chip.

According to the packaging method provided in the forms of the present disclosure, in the chipset, a portion of the bottom chip is exposed from the top chip, and the second chip is bonded to the bottom chip exposed from the top chip and the bonding surface on the side of the chipset. In the forms of the present disclosure, since a portion of the bottom chip is exposed from the top chip, a space can be provided for bonding the second chip to the bottom chip, so that a portion of the second chip can be bonded to the bottom chip exposed from the top chip, thereby electrically connecting each first chip in the chipset to the second chip. In this way, the electrical connection between the first chip and the second chip can be realized merely by using the bottom chip in the chipset without using a bridge, which helps simplify a structure and shorten a transmission path between the first chip and the second chip, thereby improving a speed of communication between the first chip and the second chip.

### BRIEF DESCRIPTION OF THE DRAWINGS

FIG. 1 is a schematic structural diagram of a packaging structure.

FIG. 2 to FIG. 3 are schematic structural diagrams of a packaging structure according to a form of the present disclosure.

FIG. 4 to FIG. 9 are schematic structural diagrams corresponding to steps in a packaging method according to a form of the present disclosure.

FIG. 10 is a flowchart of a packaging method according to a form of the present disclosure.

### DETAILED DESCRIPTION

It can be learned from the background that, current packaging structures are relatively complex, and a speed of communication between chips is to be improved. The reason why the speed of communication is to be improved is analyzed with reference to a packaging structure.

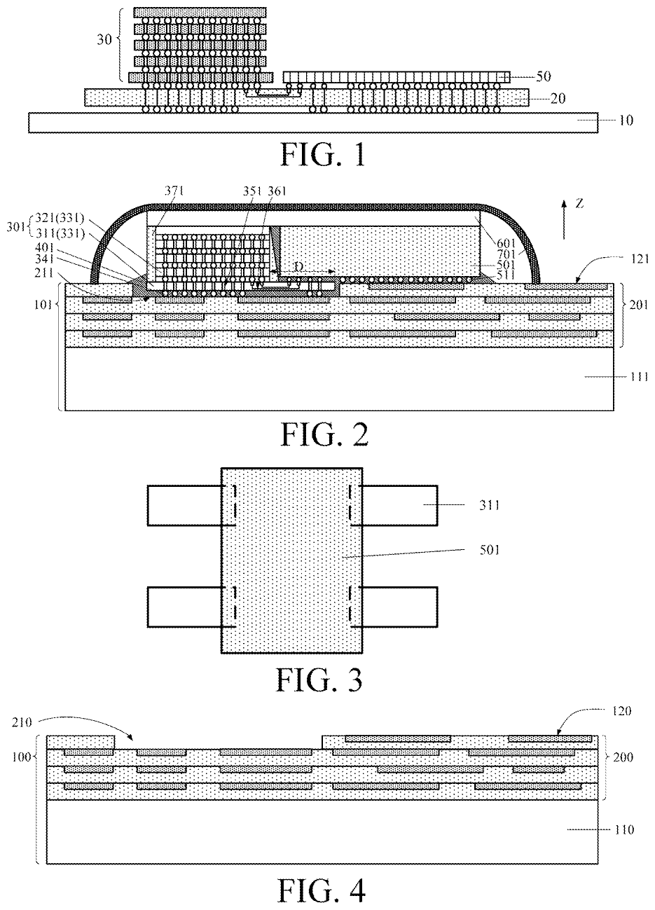

FIG. 1 is a schematic structural diagram of a packaging structure.

The packaging structure includes: a substrate 10, including a bonding surface; a silicon bridge (Si bridge) 20, bonded to the bonding surface of the substrate 10; a chipset 30, bonded to the Si bridge 20, where the chipset 30 is electrically connected to the substrate 10 by the Si bridge 20; and a chip 50, bonded to the Si bridge 20 on a side of the chipset 30, where the chip 50 is electrically connected to the substrate 10 by the Si bridge 20, and the chip 50 is electrically connected to the chipset 30 by the Si bridge 20.

Electrically connecting the chipset 30 to the chip 50 by the Si bridge 20 leads to a relatively complex packaging structure, relatively high costs for the packaging structure, and a relatively long transmission path between the chipset 30 and the chip 50, resulting in a difficulty in improving a speed of communication between the chipset 30 and the chip 50.

A form of the present disclosure provides a packaging structure, including: a substrate, including a bonding surface, a chipset, bonded to the bonding surface and including a plurality of first chips stacked along a longitudinal direction, where the first chip closest to the substrate is used as a bottom chip, each of the rest of the first chips is used as a top chip, the bottom chip is electrically connected to the substrate and the longitudinally adjacent first chip, and a portion of the bottom chip is exposed from the top chip; and a second chip, bonded to the bottom chip exposed from the top chip and to the bonding surface on a side of the chipset, where the second chip is electrically connected to the bottom chip and the substrate, and is electrically connected to the top chip by the bottom chip, and a projection of the second chip and a projection of the bottom chip on a projection plane parallel to the bonding surface partially overlap.

In the forms of the present disclosure, since a portion of the bottom chip is exposed from the top chip, a space can be provided for bonding the second chip to the bottom chip, so that a portion of the second chip can be bonded to the bottom chip exposed from the top chip, thereby electrically connecting each first chip in the chipset to the second chip. In this way, the electrical connection between the first chip and the second chip can be realized merely by using the bottom chip in the chipset without using a bridge, which helps simplify a structure and shorten a transmission path between the first chip and the second chip, thereby improving a speed of communication between the first chip and the second chip.

In order to make the foregoing objectives, features, and advantages of the forms of the present disclosure more apparent and easier to understand, specific forms of the present disclosure are described in detail below with reference to the accompanying drawings.

FIG. 2 and FIG. 3 are schematic structural diagrams of a packaging structure according to a form of the present disclosure.

The packaging structure includes: a substrate 101, including a bonding surface 121; a chipset 301, bonded to the bonding surface 121 and including a plurality of first chips 331 stacked along a longitudinal direction (shown by a direction Z in FIG. 2), where the first chip 331 adjacent to the substrate 101 is used as a bottom chip 311, each of the rest of the first chips 331 is used as a top chip 321, the bottom chip 311 is electrically connected to the substrate 101 and the adjacent first chip 331, and a portion of the bottom chip 311 is exposed from the top chip 321; and a second chip 501, bonded to the bottom chip 311 exposed from the top chip 321 and to the bonding surface 121 on a side of the chipset 301, where the second chip 501, the bottom chip 311, the top chip 321, and the substrate 101 are electrically connected, and a projection of the second chip 501 and a projection of the bottom chip 311 on a projection plane parallel to the bonding surface 121 partially overlap.

The substrate 101 is configured to provide a process operation platform for bonding the chipset 301 to the second chip 501. Specifically, the bonding surface 121 of the substrate 101 is the process operation platform.

In this form, the substrate 101 includes a base 111 and an interconnecting structure layer 201 on the base 111, and a surface exposed from the interconnecting structure layer 201 is the bonding surface 121.

The interconnecting structure layer 201 is configured to be bonded to the chipset 301 and the second chip 501, so as to be electrically connected to the chipset 301 and the second chip 501. The interconnecting structure layer 201 is further configured to be electrically connected to the base 111. Correspondingly, the chipset 301 and the second chip 501 can be electrically connected to the base 111.

In this form, the interconnecting structure layer 201 is a redistribution structure (Redistribution Layer). Specifically, the redistribution structure may include one or more redistribution layers. In this form, the redistribution structure includes a plurality of redistribution layers, for example.

The base 111 is configured to be electrically connected to the chipset 301 and the second chip 501 by the interconnecting structure layer 201, and can be electrically connected to an external structure correspondingly, so that the chipset 301 and the second chip 501 can be electrically connected to the external structure.

Specifically, in this form, the base 111 is a packaging base, and the packaging base is a printed circuit board (PCB).

In this form, a groove 211 is formed in the substrate 101 on a side of the bonding surface 121.

Since the second chip 501 is bonded to the bottom chip 311 exposed from the top chip 321 and the bonding surface 121 on the side of the chipset 301, the groove 211 is configured for the bottom chip 311 to be bonded therein, so as to reduce a height difference between a top surface of the bottom chip 311 and the bonding surface 121 on the side of the chipset 301 for bonding the second chip 501, thereby reducing a difficulty of bonding the second chip 501 to the bottom chip 311 and the bonding surface 121 on the side of the chipset 301, and helping improve bonding reliability of the second chip 501. In addition, an excessively large gap is avoided between a bottom of the second chip 501 and the bonding surface 121 on the side of the chipset 301, which helps avoid a difficulty in the bonding as a result of an excessively large gap between the bottom of the second chip 501 and the bonding surface 121 on the side of the chipset 301. In this way, the second chip 501 can be easily bonded, and performance of the packaging structure is correspondingly ensured.

The chipset 301 is configured to be electrically connected to the second chip 501, to electrically connect the first chip 331 to the second chip 501, so as to form a corresponding packaging structure and realize corresponding functions.

In this form, in the chipset 301, the plurality of first chips 331 stacked along the longitudinal direction form a high-bandwidth memory (HBM) structure. The HBM structure helps satisfy a demand for a higher information transmission speed.

One or more top chips 321 may be arranged. In this form, four top chips 321 are arranged, for example. In other forms, another number of top chips may be arranged.

Therefore, in this form, the top chip 321 is a memory chip. During specific implementation, the top chip 321 is an HBM chip.

In this form, the bottom chip 311 is a first logic chip. Specifically, the bottom chip 311 is used as a logic control chip in the chipset 301.

In this form, the bottom chip 311 is electrically connected to the substrate 101 and the longitudinally adjacent first chip 331, so as to realize electrical integration between the first chips 331 and between the first chip 331 and the substrate 101.

Specifically, in this form, the bottom chip 311 is electrically connected to the interconnecting structure layer 201. Therefore, the bottom chip 311 can be electrically connected to the base 111.

In this form, along a direction of the surface of the bottom chip 311, a transverse dimension of the bottom chip 311 is greater than a transverse dimension of the top chip 321, and a portion of the bottom chip 311 is exposed from the top chip 321, so that a space can be provided for bonding the second chip 501 to the bottom chip 311, and therefore a portion of the second chip 501 can be bonded to the bottom chip 311 exposed from the top chip 321, thereby electrically connecting each first chip 331 in the chipset 301 to the second chip 501. In this way, the electrical connection between the first chip 331 and the second chip 501 can be realized merely by using the bottom chip 311 in the chipset 301 without using a bridge, which helps simplify a structure and shorten a transmission path between the first chip 331 and the second chip 501, thereby improving a speed of communication between the first chip 331 and the second chip 501.

In this form, since the bottom chip 311 is arranged in the groove 211, the height difference between the top surface of the bottom chip 311 and the bonding surface 121 on the side of the chipset 301 for bonding the second chip 501 is reduced. Therefore, the difficulty of bonding the second chip 501 to the bottom chip 311 and to the bonding surface 121 on the side of the chipset 301 is reduced.

In this form, the height difference between the top surface of the bottom chip 311 and the bonding surface 121 on an outer side of the groove 211 is relatively small. For example, the top surface of the bottom chip 311 is flush with the bonding surface 121 on the outer side of the groove 211, or the top surface of the bottom chip 311 is slightly lower than the bonding surface 121 on the outer side of the groove 211, or the top surface of the bottom chip 311 is slightly higher than the bonding surface 121 on the outer side of the groove 211.

In this form, a first interconnecting structure 361 is formed in the bottom chip 311 exposed from the top chip 321, and the first interconnecting structure 361 is electrically connected to the top chip 321.

The first interconnecting structure 361 is configured to be electrically connected to the top chip 321, so as to electrically lead out the top chip 321 and be used as an external port of the top chip 321.

In this form, a material of the first interconnecting structure 361 is a metal material, such as one or more of copper, aluminum, tungsten, cobalt, nickel, titanium, tantalum, titanium nitride, or tantalum nitride.

In this form, a second interconnecting structure 351 extending through the bottom chip 311 is further formed in the bottom chip 311, and the substrate 101 is electrically connected to the top chip 321 longitudinally adjacent to the bottom chip 311 by the second interconnecting structure 351.

The second interconnecting structure 351 is configured to electrically connect each first chip 331 to the substrate 101.

In this form, the second interconnecting structure 351 is a through-silicon-via (TSV) structure. Through the TSV structure, the first chips 331 can be stacked in a three-dimensional direction relatively densely, have relatively small external dimensions, and greatly increase the speed of the chips and reduce power consumption of the chips.

In this form, a material of the second interconnecting structure 351 is a metal material, such as one or more of copper, aluminum, tungsten, cobalt, nickel, titanium, tantalum, titanium nitride, or tantalum nitride.

In this form, a plurality of chipsets 301 are arranged, and the plurality of chipsets 301 are electrically connected to the second chip 501, which helps increase a memory of the packaging structure, improve a speed of the chip, and reduce power consumption of the chip.

In this form, the packaging structure further includes first conductive bumps 341 arranged between the bottom chip 311 and the substrate 101 and electrically connecting the bottom chip 311 to the substrate 101.

The first conductive bumps 341 are configured to electrically connect the interconnecting structure layer 201 to the bottom chip 311.

In this form, a material of each of the first conductive bumps 341 includes one or more of tin, copper, aluminum, tungsten, cobalt, nickel, titanium, tantalum, titanium nitride, or tantalum nitride. In an example, the material of the first conductive bump 341 is tin.

For example, the first conductive bump 341 may be controlled collapse chip connection (C4), which has excellent electrical and thermal properties. In case of a same first conductive bump spacing, C4 can achieve a very high I/O quantity, and is free of limitation by a size of a redistribution structure. In addition, C4 is suitable for mass production and greatly reduces a size and a weight.

The second chip 501 is configured to be electrically connected to the bottom chip 311 to electrically connect the second chip 501 to each first chip 331.

The second chip 501 is configured to be electrically connected to the substrate 101. Specifically, the second chip 501 is electrically connected to the interconnecting structure layer 201, and correspondingly realizes electrical connection between the second chip 501 and the base 111, thereby realizing a layout of the circuit structure according to an actual demand.

In this form, the second chip 501 may be directly electrically connected to the interconnecting structure layer 201. The second chip 501 may alternatively be electrically connected to the interconnecting structure layer 201 by the bottom chip 311.

Referring to FIG. 3, FIG. 3 is a top view of FIG. 2. In this form, the second chip 501 is bonded to the bottom chip 311 exposed from the top chip 321. Therefore, a projection of second chip 501 and a projection of the bottom chip 311 on a projection plane parallel to the bonding surface 121 partially overlap.

Specifically, in this form, the second chip 501 partially overlaps and is electrically connected to each of the bottom chips 311 of a plurality of adjacent chipsets 301, so as to realize electrical integration of the second chip 501 with the plurality of chipsets 301. In an example, as shown in FIG. 3, four chipsets 301 are arranged. An overlapping region exists between the second chip 501 and each of the four adjacent bottom chips 311, and the second chip is electrically connected to each of the four adjacent bottom chips 311.

In this form, the second chip 501 is a second logic chip configured to control the memory chip of the chipset 301. Specifically, the second logic chip may be a central processing unit (CPU) chip, a graphics processing unit (GPU) chip, or a system on chip (SoC).

In this form, the packaging structure further includes second conductive bumps 511 arranged between the second chip 501 and the bottom chip 311 and between the second chip 501 and the substrate 101, where the second conductive bumps 511 electrically connect the second chip 501 to the bottom chip 311 and electrically connect the second chip 501 to the substrate 101.

The second conductive bumps 511 are configured to electrically connect the second chips 501 to the bottom chip 311. The second conductive bumps 511 are further configured to electrically connect the second chip 501 to the substrate 101.

In this form, a material of each of the second conductive bumps 511 includes one or more of tin, copper, aluminum, tungsten, cobalt, nickel, titanium, tantalum, titanium nitride, or tantalum nitride. In an example, the material of the second conductive bump 511 is tin.

In this form, the second conductive bumps 511 arranged between the second chip 501 and the bottom chip 311 may be microbumps, and the microbumps are arranged relatively densely, thereby helping improve the speed of communication between the second chip 501 and the bottom chip 311.

In this form, the packaging structure further includes a sealing layer 401 arranged between the bottom chip 311 and the substrate 101 and between the second chip 501 and the substrate 101 and filling a gap between an adjacent top chip 321 and the second chip 501, a gap between adjacent first conductive bumps 341, and a gap between adjacent second conductive bumps 511.

The sealing layer 401 is configured to seal the chipset 301 and the second chip 501, and also to seal the first conductive bumps 341 and the second conductive bumps 511.

In this form, the second chip 501 is bonded to the bottom chip 311 exposed from the top chip 321. Therefore, the second chip 501 and the chipset 301 can be sealed in a same step, which helps improve process efficiency.

In this form, the packaging structure further includes a molding layer 371 covering a sidewall of the first chip 331 and from which the bottom chip 311 on a side of the top chip 321 is exposed.

The molding layer 371 is configured to protect the structure of the chipset 301 and expose the bottom chip 311 on the side of the top chip 321, to provide a space for bonding the second chip 501 to the bottom chip 311.

In this form, a material the molding layer 371 is a molding material, for example, epoxy resin. Epoxy resin has advantages such as low shrinkage, desirable viscosity, desirable corrosion resistance, excellent electrical properties, and low costs. In other forms, the first molding layer may be made of other suitable packaging materials.

In this form, the packaging structure further includes a thermally conductive layer 601 arranged on the chipset 301 and a top of the second chip 501.

The thermally conductive layer 601 is configured to realize heat conduction and heat dissipation.

In this form, a material of the thermally conductive layer 601 is a thermal interface material (TIM). For example, the material of the thermally conductive layer 601 is silica gel.

In this form, the packaging structure further includes a packaging housing 701 arranged on the substrate 101 and packaging the packaging structure. Specifically, in this form, the packaging housing 701 is in contact with the thermally conductive layer 601, so that the thermally conductive layer 601 realizes heat dissipation.

The packaging housing 601 is configured for mechanical protection of the chips inside and transitional connection of chip electrodes to the outside, and helps ensure correct realization of various functional parameters of the chips and environmental conditions required when the circuit is used.

In this form, a material of the packaging housing 601 includes metal, that is, the packaging housing 601 is a metal packaging housing. In other forms, the packaging housing may be a plastic packaging housing, a ceramic packaging housing, or the like.

An form of the present disclosure provides a packaging method 1000 as shown in FIG. 10. FIG. 4 to FIG. 9 are schematic structural diagrams corresponding to steps in the packaging method 1000.

Referring to FIG. 4, a substrate 100 is provided, including a bond surface 120 (1001).

The substrate 100 is configured to provide a process operation platform for subsequently bonding the chipset to the second chip. Specifically, the bonding surface 120 of the substrate 100 is the process operation platform.

In this form, the substrate 100 includes a base 110 and an interconnecting structure layer 200 on the base 110, and a surface exposed from the interconnecting structure layer 200 is the bonding surface 120.

In this form, the base 110 is a packaging base, and the packaging base is a PCB.

The interconnecting structure layer 200 is configured to be subsequently bonded to the chipset and the second chip, so as to be electrically connected to the chipset and the second chip. The interconnecting structure layer 200 is further configured to be electrically connected to base 110. Correspondingly, the chipset and the second chip can be electrically connected to the base 110.

In this form, the interconnecting structure layer 200 is a redistribution structure. Specifically, the redistribution structure may include one or more redistribution layers. In this form, the redistribution structure includes a plurality of redistribution layers, for example.

The base 110 is configured to be subsequently electrically connected to the chipset and the second chip by the interconnecting structure layer 200, and can be electrically connected to an external structure correspondingly, so that the chipset and the second chip can be electrically connected to the external structure.

In this form, before the chipset is subsequently bonded to the bond surface 120, the method further includes: forming a groove 210 in the substrate 100 on the side of the bond surface 120.

The groove 210 is configured to provide a space for subsequently bonding the bottom chip of the chipset.

Since the second chip is subsequently bonded to the bottom chip exposed from the top chip and the bonding surface 120 on the side of the chipset, the groove 210 is configured for the bottom chip to be bonded therein, so as to reduce a height difference between a top surface of the bottom chip and the bonding surface 120 on the side of the chipset for bonding the second chip, thereby reducing a difficulty of bonding the second chip to the bottom chip and the bonding surface 120 on the side of the chipset, and helping improve bonding reliability of the second chip. In addition, an excessively large gap is avoided between a bottom of the second chip and the bonding surface 120 on the side of the chipset, which helps avoid a difficulty in the bonding as a result of an excessively large gap between the bottom of the second chip and the bonding surface 120 on the side of the chipset. In this way, the second chip can be easily bonded, and performance of the packaging structure is correspondingly ensured.

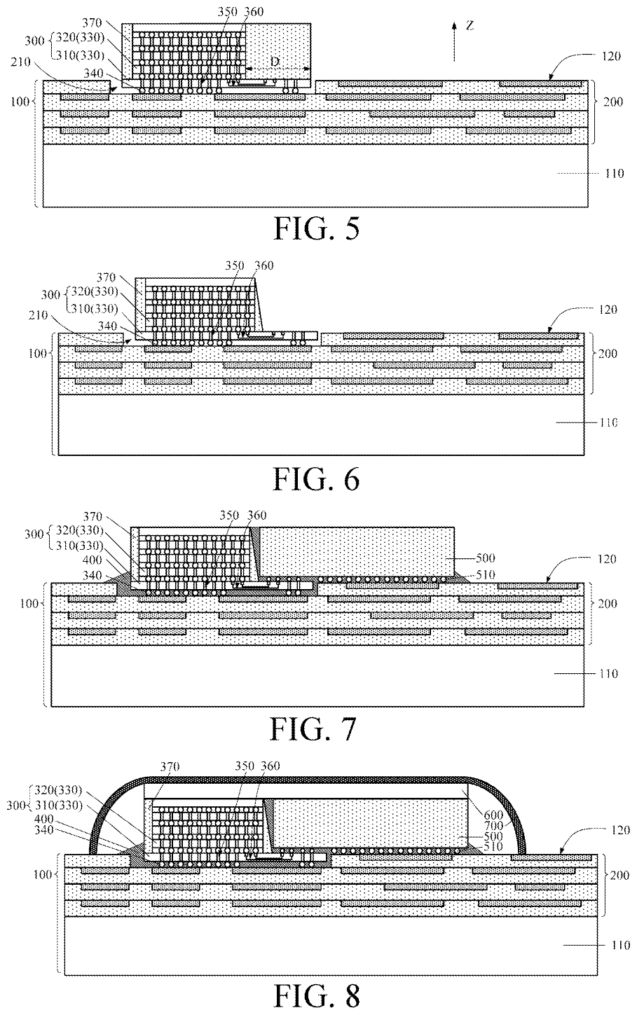

Referring to FIG. 5, a chipset 300 is provided (1002). The chipset 300 includes a plurality of first chips 330 stacked along a longitudinal direction (shown by a direction Z in FIG. 5). The first chip 330 at a bottom of the chipset 300 is used as a bottom chip 310, each of the rest of the first chips 330 is used as a top chip 320, adjacent first chips 330 along the longitudinal direction are electrically connected, and a portion of the bottom chip 310 is exposed from the top chip 320.

The chipset 300 is configured to be subsequently electrically connected to the second chip, to electrically connect the first chip 330 to the second chip, so as to form a corresponding packaging structure and realize corresponding functions.

In this form, in the chipset 300, the plurality of first chips 330 stacked along the longitudinal direction form an HBM structure. The HBM structure helps satisfy a demand for a higher information transmission speed.

One or more top chips 320 may be arranged. In this form, four top chips 320 are arranged, for example. In other forms, another number of top chips may be arranged.

Therefore, in this form, the top chip 320 is a memory chip. During specific implementation, the top chip 320 is an HBM chip.

In this form, the bottom chip 310 is a first logic chip. Specifically, the bottom chip 311 is used as a logic control chip in the chipset 300.

In this form, the bottom chip 310 is electrically connected to the substrate 100 and the longitudinally adjacent first chip 330, so as to realize electrical integration between the first chips 330 and between the first chip 330 and the substrate 100.

Specifically, in this form, the bottom chip 310 is electrically connected to the interconnecting structure layer 200, and correspondingly electrically connects the bottom chip 310 to the base 110, thereby realizing a layout of the circuit structure according to an actual demand.

In this form, along a direction of the surface of the bottom chip 310, a transverse dimension of the bottom chip 310 is greater than a transverse dimension of the top chip 320, and a portion of the bottom chip 310 is exposed from the top chip 320, so that a space can be provided for bonding the second chip to the bottom chip 310, and therefore a portion of the second chip can be bonded to the bottom chip 310 exposed from the top chip 320, thereby electrically connecting each first chip 330 in the chipset 300 to the second chip. In this way, the electrical connection between the first chip 330 and the second chip can be realized merely by using the bottom chip 310 in the chipset 300 without using a bridge, which helps simplify a structure and shorten a transmission path between the first chip 330 and the second chip, thereby improving a speed of communication between the first chip 330 and the second chip.

In this form, since the bottom chip 310 is arranged on the bonding surface 120 in the groove 210, the height difference between the top surface of the bottom chip 310 and the bonding surface 120 on the side of the chipset 300 for bonding the second chip is reduced. Therefore, the difficulty of bonding the second chip to the bottom chip 310 and to the bonding surface 120 on the side of the chipset 300 is reduced.

In this form, the height difference between the top surface of the bottom chip 310 and the bonding surface 120 on an outer side of the groove 210 is relatively small. For example, the top surface of the bottom chip 310 is flush with the bonding surface 120 on the outer side of the groove 210, or the top surface of the bottom chip 310 is slightly lower than the bonding surface 120 on the outer side of the groove 210, or the top surface of the bottom chip 310 is slightly higher than the bonding surface 120 on the outer side of the groove 210.

In this form, a first interconnecting structure 360 is formed in the bottom chip 310 exposed from the top chip 320, and the first interconnecting structure 360 is electrically connected to the top chip 320.

The first interconnecting structure 360 is configured to be electrically connected to the top chip 320, so as to electrically lead out the top chip 321 and be used as an external port of the top chip 320.

In this form, a material of the first interconnecting structure 360 is a metal material, such as one or more of copper, aluminum, tungsten, cobalt, nickel, titanium, tantalum, titanium nitride, or tantalum nitride.

In this form, a second interconnecting structure 350 extending through the bottom chip 310 is further formed in the bottom chip 310, and the substrate 100 is electrically connected to the top chip 320 longitudinally adjacent to the bottom chip 310 by the second interconnecting structure 350.

The second interconnecting structure 350 is configured to subsequently electrically connect each first chip 330 to the substrate 100.

In this form, the second interconnecting structure 350 is a TSV structure. Through the TSV structure, the first chips 330 can be stacked in a three-dimensional direction relatively densely, have relatively small external dimensions, and greatly increase the speed of the chips and reduce power consumption of the chips.

In this form, a material of the second interconnecting structure 350 is a metal material, such as one or more of copper, aluminum, tungsten, cobalt, nickel, titanium, tantalum, titanium nitride, or tantalum nitride.

In this form, a plurality of chipsets 300 are arranged, and the plurality of chipsets 300 are subsequently electrically connected to the second chip, which helps increase a memory of the packaging structure, improve a speed of the chip, and reduce power consumption of the chip.

In this form, in the step of providing the chipset 300, a molding layer 370 is formed on a sidewall of the first chip 330, and the molding layer 370 further covers the bottom chip 310 exposed from the top chip 320.

The molding layer 370 covers a sidewall of the first chip 330 and the bottom chip 310 exposed from the top chip 320, to protect the structure of the chipset 300.

In this form, a material the molding layer 370 is a molding material, for example, epoxy resin. Epoxy resin has advantages such as low shrinkage, desirable viscosity, desirable corrosion resistance, excellent electrical properties, and low costs. In other forms, the first molding layer may be made of other suitable packaging materials.

Referring to FIG. 5 and FIG. 6, the chipset 300 is bonded to the bond surface 120 (1003). In the chipset 300, the bottom chip 310 is adjacent to the bond surface 120, and the bottom chip 310 is electrically connected to the substrate 100.

The chipset 300 is bonded on the bond surface 120 to realize the electrical connection between each first chip 330 and the substrate 100. Specifically, in this form, the second interconnecting structure 350 is electrically connected to the substrate 100, so as to realize the electrical connection between each first chip 330 and the substrate 100.

In this form, the bottom chip 310 is electrically connected to the interconnecting structure layer 200. Therefore, the bottom chip 310 can be electrically connected to the base 110.

In this form, since a portion of the bottom chip 310 is exposed from the top chip 320, a space can be provided for bonding the second chip to the bottom chip 310, so that a portion of the second chip can be bonded to the bottom chip 310 exposed from the top chip 320, thereby electrically connecting each first chip 330 in the chipset 300 to the second chip. In this way, the electrical connection between the first chip 330 and the second chip can be realized merely by using the bottom chip 310 in the chipset without using a bridge, which helps simplify a structure and shorten a transmission path between the first chip 330 and the second chip, thereby improving a speed of communication between the first chip 330 and the second chip.

In this form, in the step of bonding the chipset 300 to the bond surface 120, since the chipset 300 is bonded to the bond surface 120 at the bottom of the groove 210, the height difference between the top surface of the bottom chip 310 and the bonding surface 120 on the side of the chipset 300 for bonding the second chip is reduced, so that the difficulty of bonding the second chip to the bottom chip and to the bonding surface 120 on the side of the chipset is reduced.

In this form, the step of bonding the chipset 300 to the bond surface 120 includes: forming first conductive bumps 340 on a surface of the bottom chip 310 facing away from the top chip 320 or on the substrate 100; and bonding the bottom chip 310 to the substrate 100 by using the first conductive bumps 340, where the first conductive bumps 340 electrically connect the bottom chip 310 to the substrate 100.

The first conductive bumps 340 are configured to electrically connect the substrate 100 to the bottom chip 310.

In this form, a material of each of the first conductive bumps 340 includes one or more of tin, copper, aluminum, tungsten, cobalt, nickel, titanium, tantalum, titanium nitride, or tantalum nitride. In an example, the material of the first conductive bump 340 is tin.

For example, the first conductive bump 340 may be C4, which has excellent electrical and thermal properties. In case of a same first conductive bump spacing, C4 can achieve a very high I/O quantity, and is free of limitation by a size of a redistribution structure. In addition, C4 is suitable for mass production and greatly reduces a size and a weight.

Referring to FIG. 6, in this form, after the chipset 300 is bonded to the bond surface 120 and before the second chip is subsequently bonded to the bottom chip 310 exposed from the top chip 320, the method further includes: removing the molding layer 370 covering the bottom chip 310, to expose a top of the bottom chip 310 on a side of the top chip 320.

Removing the molding layer 370 covering the bottom chip 310 to expose the top of the bottom chip 310 on the side of the top chip 320 provides a space for subsequently bonding the second chip to the bottom chip 310.

Referring to FIG. 7, a second chip 500 is provided (1004).

The second chip 500 is configured to be subsequently electrically connected to the bottom chip 310 to electrically connect the second chip 500 to each first chip 330.

In this form, the second chip 500 is a second logic chip configured to control the memory chip of the chipset 301. Specifically, the second logic chip may be a CPU chip, a GPU chip, or an SoC chip.

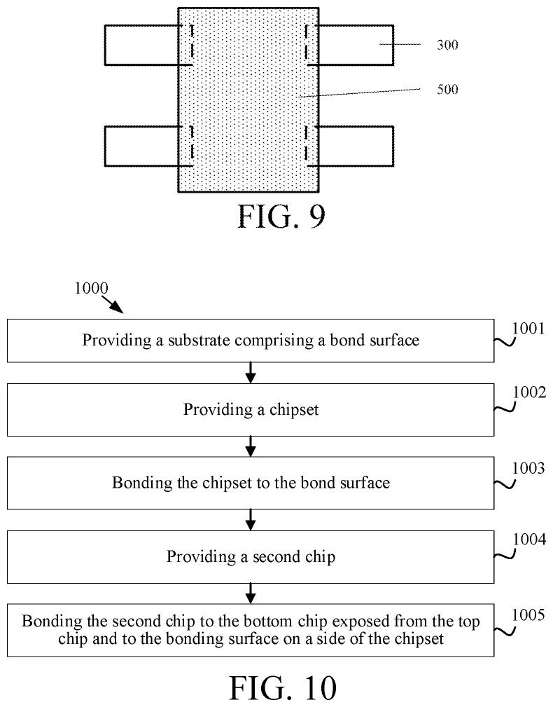

Referring to FIG. 8 and FIG. 9, FIG. 9 is a top view of FIG. 8. A second chip 500 is bonded to the bottom chip 310 exposed from the top chip 320 and to the bonding surface 120 on a side of the chipset 300 (1005), the second chip 500, the bottom chip 310, the top chip 320, and the substrate 100 are electrically connected, and a projection of the second chip 500 and a projection of the bottom chip 310 on the bonding surface 120 partially overlap.

The second chip 500 is configured to be electrically connected to the bottom chip 310 to realize electrical connection between the second chip 500 and each first chip 330, and is further configured to be electrically connected to the substrate 100. Specifically, the second chip 500 is electrically connected to the first interconnecting structure 360, and correspondingly, the second chip 500 can be electrically connected to the bottom chip 310, and the second chip 500 is electrically connected to the interconnecting structure layer 200, and correspondingly, the second chip 500 can be electrically connected to the base 110, thereby realizing a layout of the circuit structure according to an actual demand.

In this form, the second chip 500 may be directly electrically connected to the interconnecting structure layer 200. The second chip 500 may alternatively be electrically connected to the interconnecting structure layer 200 by the bottom chip 310.

Referring to FIG. 9, in this form, the second chip 500 is bonded to the bottom chip 310 exposed from the top chip 320. Therefore, a projection of second chip 500 and a projection of the bottom chip 310 on a projection plane parallel to the bonding surface 120 partially overlap.

Specifically, in this form, the second chip 500 partially overlaps and is electrically connected to each of the bottom chips 310 of a plurality of adjacent chipsets 300, so as to realize electrical integration of the second chip 500 with the plurality of chipsets 300. In an example, as shown in FIG. 9, four chipsets 300 are arranged. An overlapping region exists between the second chip 500 and each of the four adjacent bottom chips 310, and the second chip is electrically connected to each of the four adjacent bottom chips 310.

In this form, the step of bonding the second chip 500 to the bottom chip 310 exposed from the top chip 320 and to the bonding surface 120 on the side of the chipset 300 includes: forming second conductive bumps 510 on the bottom chip 310 and the substrate 100 or forming second conductive bumps 510 on the second chip 500; and bonding the second chip 500 to the bottom chip 310 and the substrate 100 by the second conductive bumps 510, where the second conductive bumps 510 electrically connect the second chip 500 to the bottom chip 310 and electrically connect the second chip 500 to the substrate 100.

The second conductive bumps 510 are configured to electrically connect the second chips 500 to the bottom chip 310. The second conductive bumps 510 are further configured to electrically connect the second chip 500 to the substrate 100.

In this form, a material of each of the second conductive bumps 510 includes one or more of tin, copper, aluminum, tungsten, cobalt, nickel, titanium, tantalum, titanium nitride, or tantalum nitride. In an example, the material of the second conductive bump 510 is tin.

In this form, the second conductive bumps 510 arranged between the second chip 500 and the bottom chip 310 may be microbumps, and the microbumps are densely arranged, thereby helping improve the speed of communication between the second chip 500 and the bottom chip 310.

In this form, after the second chip 500 is bonded to the bottom chip 310 exposed from the top chip 320 and to the bonding surface 120 on the side of the chipset 300, the packaging method further includes: filling the bond surface 120 with a sealing layer 400, where the sealing layer 400 is arranged between the bottom chip 310 and the substrate 100 and between the second chip 500 and the substrate 100, and fills a gap between the top chip 320 and the second chip 500, a gap between adjacent first conductive bumps 340, and a gap between adjacent second conductive bumps 510.

The sealing layer 400 is configured to seal the chipset 300 and the second chip 500, and also to seal the first conductive bumps 340 and the second conductive bumps 510.

In this form, after the second chip 500 is bonded to the bottom chip 310 exposed from the top chip 320 and to the bonding surface 120 on the side of the chipset 300, the sealing layer 400 is used for filling, so that the second chip 500 and the chipset 300 both can be sealed, which improves process efficiency.

In this form, the packaging method further includes: forming a thermally conductive layer 600 covering the chipset 300 and the top of the second chip 500.

The thermally conductive layer 600 is configured to realize heat conduction and heat dissipation.

In this form, a material of the thermally conductive layer 600 is a TIM. For example, the material of the thermally conductive layer 600 is silica gel.

In this form, the packaging method further includes: forming, on the substrate 100, a packaging housing 700 packaging the packaging structure after forming the thermally conductive layer 600. Specifically, in this form, the packaging housing 700 is in contact with the thermally conductive layer 600, so that the thermally conductive layer 600 realizes heat dissipation.

The packaging housing 600 is configured for mechanical protection of the chips inside and transitional connection of chip electrodes to the outside, and helps ensure correct realization of various functional parameters of the chips and environmental conditions required when the circuit is used.

In this form, a material of the packaging housing 600 includes metal, that is, the packaging housing 600 is a metal packaging housing. In other forms, the packaging housing may be a plastic packaging housing, a ceramic packaging housing, or the like.

Although the present disclosure is disclosed above, the present disclosure is not limited thereto. Any person skilled in the art can make various changes and modifications without departing from the spirit and the scope of the present disclosure. Therefore, the protection scope of the present disclosure should be subject to the scope defined by the claims.

What is claimed is:

1. A packaging structure, comprising:
a substrate, comprising a bonding surface,
a chipset, bonded to the bonding surface and comprising a plurality of first chips stacked along a longitudinal direction, wherein a first chip of the plurality of first chips that is adjacent to the substrate is used as a bottom chip, each of the rest of the first chips of the plurality of first chips is used as a top chip, the bottom chip is electrically connected to the substrate and an adjacent first chip of the plurality of first chips, and a portion of the bottom chip is exposed from the top chip; and
a second chip, bonded to the bottom chip exposed from the top chip and to the bonding surface on a side of the chipset, wherein the second chip, the bottom chip, the top chip, and the substrate are electrically connected, and a projection of the second chip and a projection of the bottom chip on a projection plane parallel to the bonding surface partially overlap.

2. The packaging structure according to claim 1, wherein a groove is formed in the substrate on a side of the bonding surface, and the bottom chip is arranged in the groove.

3. The packaging structure according to claim 1, wherein a first interconnecting structure is formed in the bottom chip exposed from the top chip, the first interconnecting structure is electrically connected to the top chip, and the second chip bonded to the bottom chip is electrically connected to the first interconnecting structure.

4. The packaging structure according to claim 1, wherein a second interconnecting structure extending through the bottom chip is formed in the bottom chip, and the substrate is electrically connected to the top chip longitudinally adjacent to the bottom chip by the second interconnecting structure.

5. The packaging structure according to claim 1, further comprising:
first conductive bumps, arranged between the bottom chip and the substrate, and electrically connecting the bottom chip to the substrate; and
second conductive bumps, arranged between the second chip and the bottom chip, and between the second chip and the substrate, wherein the second conductive bumps electrically connect the second chip to the bottom chip and electrically connect the second chip to the substrate.

6. The packaging structure according to claim 5, further comprising:
a sealing layer arranged between the bottom chip and the substrate and between the second chip and the substrate, and filling a gap between the top chip and the second chip, a gap between adjacent first conductive bumps, and a gap between adjacent second conductive bumps.

7. The packaging structure according to claim 1, further comprising a plurality of chipsets, wherein the second chip partially overlaps and is electrically connected to each of the bottom chips of a plurality of adjacent chipsets.

8. The packaging structure according to claim 1, wherein:
the substrate comprises a base and an interconnecting structure layer on the base,
a surface exposed from the interconnecting structure layer is the bonding surface, and
the bottom chip is electrically connected to the interconnecting structure layer, and the second chip is electrically connected to the interconnecting structure layer.

9. The packaging structure according to claim 1, wherein the bottom chip is a first logic chip, the top chip is a memory chip, and the second chip is a second logic chip.

10. The packaging structure according to claim 1, further comprising a molding layer covering a sidewall of the first chip, and the bottom chip on a side of the top chip is exposed from the molding layer.

11. The packaging structure according to claim 1, further comprising a thermally conductive layer arranged on the chipset and a top of the second chip.

12. The packaging structure according to claim 1, further comprising a packaging housing arranged on the substrate and packaging the packaging structure.

13. A packaging method, comprising:
providing a substrate comprising a bond surface;
providing a chipset, wherein the chipset comprises a plurality of first chips stacked along a longitudinal direction, a first chip of the plurality of first chips at a bottom of the chipset is used as a bottom chip, each of the rest of the first chips is used as a top chip, adjacent first chips of the plurality of first chips along the longitudinal direction are electrically connected, and a portion of the bottom chip is exposed from the top chip;
bonding the chipset to the bond surface, wherein in the chipset, the bottom chip is adjacent to the bond surface, and the bottom chip is electrically connected to the substrate;
providing a second chip; and
bonding the second chip to the bottom chip exposed from the top chip and to the bonding surface on a side of the chipset, wherein the second chip, the bottom chip, the top chip, and the substrate are electrically connected, and a projection of the second chip and a projection of the bottom chip on the bonding surface partially overlap.

14. The packaging method according to claim 13, wherein before the bonding of the chipset to the bond surface, the method further comprises:
forming a groove in the substrate on a side of the bond surface; and
the bonding of the chipset to the bond surface comprises:
bonding the chipset to the bond surface at a bottom of the groove.

15. The packaging method according to claim 13, wherein in the step of providing the chipset, a molding layer is formed on a sidewall of the first chip, and the molding layer covers the bottom chip exposed from the top chip, and the method further comprises:
after the bonding the chipset to the bond surface and before the bonding the second chip to the bottom chip exposed from the top chip, removing the molding layer covering the bottom chip to expose a top of the bottom chip on a side of the top chip.

16. The packaging method according to claim 13, wherein in the step of providing the chipset, a first interconnecting structure is formed in the bottom chip exposed from the top chip, and the first interconnecting structure is electrically connected to the top chip; and
in the step of bonding the second chip to the bottom chip exposed from the top chip, the second chip is electrically connected to the first interconnecting structure.

17. The packaging method according to claim 13, wherein in the step of providing the chipset, a second interconnecting structure extending through the bottom chip is formed in the bottom chip, and the top chip longitudinally adjacent to the bottom chip is electrically connected to the second interconnecting structure; and
in the step of bonding the chip set to the bond surface, the second interconnecting structure is electrically connected to the substrate.

18. The packaging method according to claim 13, wherein the bonding the chipset to the bond surface comprises:
forming first conductive bumps on a surface of the bottom chip facing away from the top chip or on the substrate;
bonding the bottom chip to the substrate using the first conductive bumps, wherein the first conductive bumps electrically connect the bottom chip to the substrate; and
the bonding the second chip to the bottom chip exposed from the top chip and to the bonding surface on the side of the chipset comprises:
forming second conductive bumps on the bottom chip and the substrate or on the second chip; and
bonding the second chip to the bottom chip and the substrate by the second conductive bumps, wherein the second conductive bumps electrically connect the second chip to the bottom chip and electrically connect the second chip to the substrate.

19. The packaging method according to claim 18, wherein the packaging method further comprises:
after the bonding the second chip to the bottom chip exposed from the top chip and to the bonding surface on the side of the chipset, filling the bond surface with a sealing layer, wherein the sealing layer is arranged between the bottom chip and the substrate and between the second chip and the substrate and fills a gap between the top chip and the second chip, a gap between adjacent first conductive bumps, and a gap between adjacent second conductive bumps.

20. The packaging method according to claim 13, wherein in the step of providing the chipset, a plurality of chipsets are arranged; and
in the step of bonding the second chip to the bottom chip exposed from the top chip and to the bonding surface on the side of the chipset, the second chip partially overlaps and is electrically connected to each of bottom chips of a plurality of adjacent chipsets.

21. The packaging method according to claim 13, wherein in the step of providing the substrate, the substrate comprises a base and an interconnecting structure layer on the base, and a surface exposed from the interconnecting structure layer is the bond surface;
in the step of bonding the chipset to the bond surface, the bottom chip is electrically connected to the interconnecting structure layer; and
in the step of bonding the second chip to the bonding surface on the side of the chipset, the second chip is electrically connected to the interconnecting structure layer.

22. The packaging method according to claim 13, wherein the bottom chip is a first logic chip, the top chip is a memory chip, and the second chip is a second logic chip.
